(19) United States
(12) Patent Application Publication
(10) Pub. No.: US 2026/0148931 A1
(43) Pub. Date: May 28, 2026

(54) GRADIENT-BASED MILLING FOR SEGMENTED ENDPOINTING DURING LAMELLAE THINNING

(71) Applicant: FEI COMPANY, Hillsboro, OR (US)

(72) Inventor: Gavin Mitchson, Portland, OR (US)

(21) Appl. No.: 18/961,343

(22) Filed: Nov. 26, 2024

(51) Int. Cl. H01J 37/304; H01J 37/305

(52) U.S. Cl. CPC H01J 37/304; H01J 37/3053; H01J 2237/30427

(57) ABSTRACT

Embodiments of the present disclosure provide methods and systems for preparing samples for imaging using gradient-based segmented endpointing. A method includes removing a first layer of material from a sample by at least directing a charged particle beam toward a surface of the sample in a pattern where the pattern corresponds to a segment of the sample, generating, after the first layer is removed, a first image that shows at least the segment, determining, based on the image, a variation in material removal between at least two sections of the segment, determining, based on the variation in material removal, a control parameter that varies one or more properties of the charged particle beam across the at least two sections, and removing a second layer of material from the sample by at least directing the charged particle beam in the pattern according to the control parameter.

The present disclosure is directed to charged particle microscopy. More particularly, the present disclosure describes methods and systems for sample preparation using segmented endpoints.

### BACKGROUND

Charged particle microscopy can be used to investigate and analyze samples, for example using transmission electron microscopes (TEM). To view samples with a TEM, thin lamellae are formed from the sample including various structures and other features to be imaged with the TEM. Lamellae are thin membranes that are partially transparent to electrons and are typically between 7 nm to 25 nm in thickness. Due to the small dimensions of the lamellae, careful preparation of the lamellae is required to preserve structures in the sample for imaging.

### BRIEF SUMMARY

The techniques described herein are directed to systems and methods for preparing samples for imaging using gradient-based segmented endpointing.

According to one embodiment, a method includes removing a first layer of material from a sample by at least directing a charged particle beam toward a surface of the sample in a pattern where the pattern corresponds to a segment of the sample, generating, after the first layer is removed, a first image that shows at least the segment, determining, based on the image, a variation in material removal between at least two sections of the segment, determining, based on the variation in the material removal, a control parameter that varies one or more properties of the charged particle beam across the at least two sections, and removing a second layer of material from the sample by at least directing the charged particle beam in the pattern according to the control parameter.

The method may include various optional embodiments. The control parameter may include at least one of: a dosage of the charged particle beam per section of the segment, an energy level of the charged particle beam per section of the segment, a dwell time of the charged particle beam per section of the segment, or a sweep time of the charged particle beam per section of the segment. The control parameter may vary linearly across sections of the segment. The control parameter may vary non-linearly across sections of the segment. Each of the at least two sections may be mapped to a set of pixels of the pattern, and wherein the control parameter varies across at least two pixel sets of the pattern. The method may further include adjusting a width of at least one of the two sections. The method may further include outputting, by a neural network, an indication of a thickness variance across sections of the segment, wherein the control parameter is adjusted based on the indication. The method may further include outputting, by the neural network, a recommended adjustment for the control parameter. The at least two sections may be adjacent and non-overlapping. The at least two sections may have a same width. The removal of the second layer of material may be performed sequentially across sections of the segment. A total number of the sections may be N where N is predefined.

According to another embodiment, a system includes a vacuum chamber, a sample stage disposed in the vacuum chamber and configured to receive a sample in the vacuum chamber, an ion beam column configured to provide an ion beam into the vacuum chamber, and a controller comprising one or more processors and one or more memories storing computer-executable instructions that, when executed by the one or more processors, configure the controller to cause the ion beam column to remove a first layer of material from a sample by at least directing a charged particle beam toward a surface of the sample in a pattern where the pattern corresponds to a segment of the sample, process, after the first layer is removed, a first image that shows at least the segment, determine, based on the image, a variation in material removal between at least two sections of the segment, determine, based on the variation in material removal, a control parameter that varies one or more properties of the charged particle beam across the at least two sections, and cause removal of a second layer of material from the sample by at least directing the charged particle beam in the pattern according to the control parameter.

The system may include various optional embodiments. The control parameter may include at least one of: a dosage of the charged particle beam per section of the segment, an energy level of the charged particle beam per section of the segment, a dwell time of the charged particle beam per section of the segment, or a sweep time of the charged particle beam per section of the segment. The control parameter may vary linearly across sections of the segment. The control parameter may vary non-linearly across sections of the segment. Each of the at least two sections may be mapped to a set of pixels of the pattern and the control parameter may vary across at least two pixel sets of the pattern. The controller may be further configured to adjust a width of at least one of the two sections. The controller may be further configured to output, by a neural network, an indication of a material removal variance across sections of the segment, wherein determining the control parameter comprises adjusting the control parameter based on the indication.

According to another embodiment, a controller include, one or more processors and one or more memories storing computer-executable instructions that, when executed by the one or more processors, configure the controller to cause an ion beam column to remove a first layer of material from a sample by at least directing a charged particle beam toward a surface of the sample in a pattern where the pattern corresponds to a segment of the sample, cause, after the first layer is removed, a first image to be generated, the image showing at least one segment, determine, based on the image, a variation in material removal between at least two sections of the segment, determine, based on the variation in material removal, a control parameter that varies one or more properties of the charged particle beam across the at least two sections and cause removal of a second layer of material from the sample by at least directing the charged particle beam in the pattern according to the control parameter.

### BRIEF DESCRIPTION OF THE DRAWINGS

The foregoing aspects and many of the attendant advantages of the present disclosure will become more readily appreciated as the same become better understood by reference to the following detailed description, when taken in conjunction with the accompanying drawings.

FIG. 1 is a schematic diagram of an example dual beam system for preparing samples using segmented endpointing, according to some embodiments.

FIG. 2A is a diagram illustrating a view of a sample for preparation using a dual beam charged particle microscope, according to some embodiments.

FIG. 2B is a diagram illustrating another view of the sample of FIG. 2A including various structures of the sample, according to some embodiments.

FIG. 3A is an image of a cutface of a sample showing a plurality of structures, according to some embodiments.

FIG. 3B is a diagram of the cutface of FIG. 3A, identifying various structures of the sample, according to some embodiments.

FIG. 4A is a diagram illustrating milling a sample using one pattern for one segment, according to some embodiments.

FIG. 4B is a diagram illustrating the cutface of the sample of FIG. 4A with the milling stopped based on a single endpoint, according to some embodiments.

FIG. 5A is a diagram illustrating milling a sample using N patterns for N segments, according to some embodiments.

FIG. 5B is a diagram illustrating the cutface of the sample of FIG. 5A with the milling stopped in segments according to N endpoints, according to some embodiments.

FIG. 6 is a flow diagram of an example process for operating a dual beam charged particle microscope system to prepare a sample using a plurality of endpoints, according to some embodiments.

FIG. 7A is a diagram illustrating milling a sample using gradient-based segmented endpointing, according to some embodiments.

FIG. 7B is a diagram illustrating milling a sample using gradient-based segmented endpointing, according to some embodiments.

FIG. 8 is a flow diagram of an example process for milling a sample using gradient-based segmented endpointing, according to some embodiments.

FIG. 9 is a flowchart of a method for milling a sample using gradient-based segmented endpointing, according to some embodiments.

FIG. 10 depicts a block diagram of an example computer system usable with systems and methods according to embodiments of the present disclosure.

In the drawings, like reference numerals refer to like parts throughout the various views unless otherwise specified. Not all instances of an element are necessarily labeled to reduce clutter in the drawings where appropriate. The drawings are not necessarily to scale, emphasis instead being placed upon illustrating the principles being described.

### DETAILED DESCRIPTION

While exemplary embodiments have been illustrated and described, it will be appreciated that various changes can be made therein without departing from the spirit and scope of the disclosure.

Charged particle microscopy is used in various industries, including the semiconductor industry, to analyze micrometer and nanometer scale structures. For example, semiconductor devices can include nanometer scale transistors densely arranged within a silicon wafer. Images obtained with charged particle microscopy can be used to improve process control, evaluate the quality of fabricated devices, and improve yields. In the case of semiconductor devices, objects like field effect transistors (FETs) may be formed within the larger silicon wafer and adjacent to several other structures, including other FETs, vias, diode junctions, and the like. Because of the extremely small scale and dense packing of the elements, imaging of these elements can be improved by careful preparation of the sample.

Imaging samples with a charged particle microscope can include using a transmission electron microscope (TEM), a scanning electron microscope (SEM), a scanning TEM (STEM), or related techniques. To image samples using these techniques, a lamella is formed and removed from the larger substrate (e.g., the silicon wafer). The lamella can include the structures forming the devices (e.g., FETs). The lamella can be formed and removed using a dual beam charged particle microscope system, which typically includes a focused ion beam (FIB) and a scanning electron microscope (SEM). During the lamella formation process, the FIB is used to remove material from the substrate, leaving the lamella as a portion of the remaining material, while the SEM is used for imaging to guide the FIB process. This process has become conventional in many industries, not just the semiconductor industry, and is used to image and analyze almost any type of micron or nanometer scale structure buried within a surrounding substrate.

Once a lamella has been removed from the surrounding material, additional milling with the FIB can be performed to further thin the lamella. For example, an initial lamella sample from a substrate can be formed with a thickness on the order of 1 μm. Milling the lamella in one or more steps with various ion beam energies (e.g., 30 kV, 2 kV) can reduce a portion of the initial lamella sample to thicknesses of less than 100 nm, including, for example, lamellae having thicknesses of 50 nm, 20 nm, 15 nm, and less than 10 nm. By thinning the lamella, image resolution of structures within the lamella can be improved.

In the case of semiconductor devices, the continued development of smaller scale structures that are more closely packed within their substrate has led to challenges in forming suitable lamellas for imaging purposes. Small scale structures may be arranged in several layers within the same substrate, such that structures of layers in front of or behind the structure of interest can obscure or occlude the structure of interest during imaging. For example, a lamella can include a line of transistor elements (e.g., semiconductor channel fins) spaced apart from another line of transistor elements by 50 nm. To image only one line of transistor elements, the lamella can be thinned to remove the material containing the other line of transistor elements.

In many cases, the structures of interest should be at or near the surface of the lamella. Thus, milling the lamella to a suitable thickness can include removing material from the lamella until the structures of interest are at or near the surface of the lamella, as determined by imaging the surface of the lamella. Because the milling process can remove material from the structures of interest, careful control of the end point of the FIB milling is desired. This control is typically achieved by imaging the surface of the sample during milling to identify structures of interest and then comparing the shapes (e.g., dimensions like width, pitch/separation, absence of artifacts/occlusions, etc.) of the structures to the expected shape of the structures. When the imaged structures match the expected shape of the desired structures for the sample, the milling process can be stopped. As used herein, the term “endpoint” or “endpointer” can refer to the features or shape that characterizes the desired surface of the lamella, while the term “endpointing” can refer to the technique of controlling the milling of a sample based on one or more endpoints. Thus, milling of the lamella with the FIB can be stopped when the surface, or a portion thereof, matches an endpoint as determined by image analysis. Typical endpointing stops the milling of a lamella based on a portion of the lamella surface (e.g., the center of the lamella surface) matching an endpoint. Specific details about using a single endpoint to determine the depth of milling of a sample may be found in U.S. Patent Application Publication No. 2023/0307209, the contents of which are incorporated herein by reference in their entirety for all purposes.

When milling a lamella to a very small thickness (e.g., <15 nm), the lamella can exhibit warping or bending across its length, transverse to the direction of milling. This warping can cause portions of the lamella cutface to be slightly closer to or slightly further from the beam axis of the FIB than other portions of the lamella cutface. Thus, during milling with the FIB using an endpoint for a central portion of the lamella, other portions of the lamella may have too much, or too little material removed. The result can be a lamella with device structures at the surface that are damaged or distorted even though the endpoint was reached for another area of the lamella. Conventionally, operators of the dual beam system can manually correct for the warping of the lamella by adjusting the sample rotation during separate milling steps. However, such manual operations rely on operators having substantial experience making fine, manual adjustments of the dual beam system parameters, are substantially slower than automated endpointing, and typically do not yield consistent results from sample to sample.

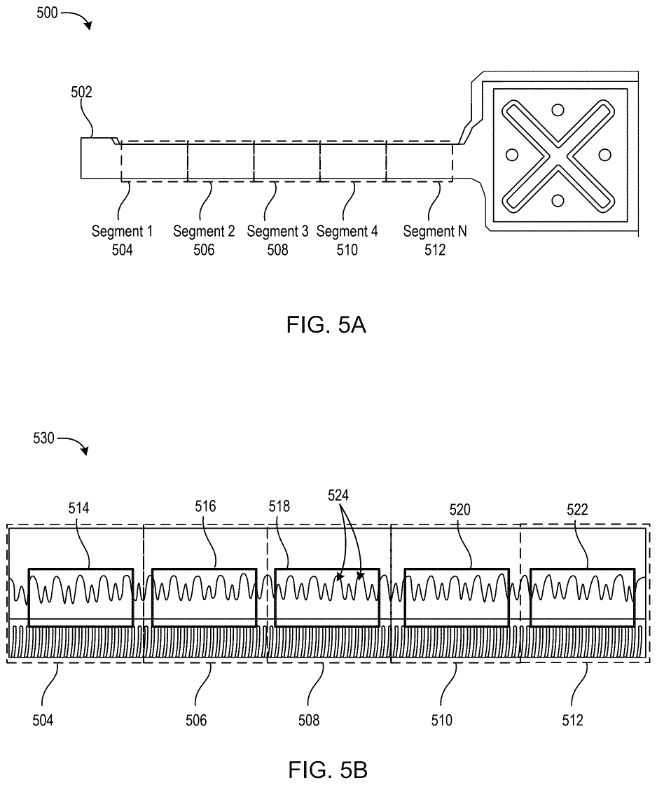

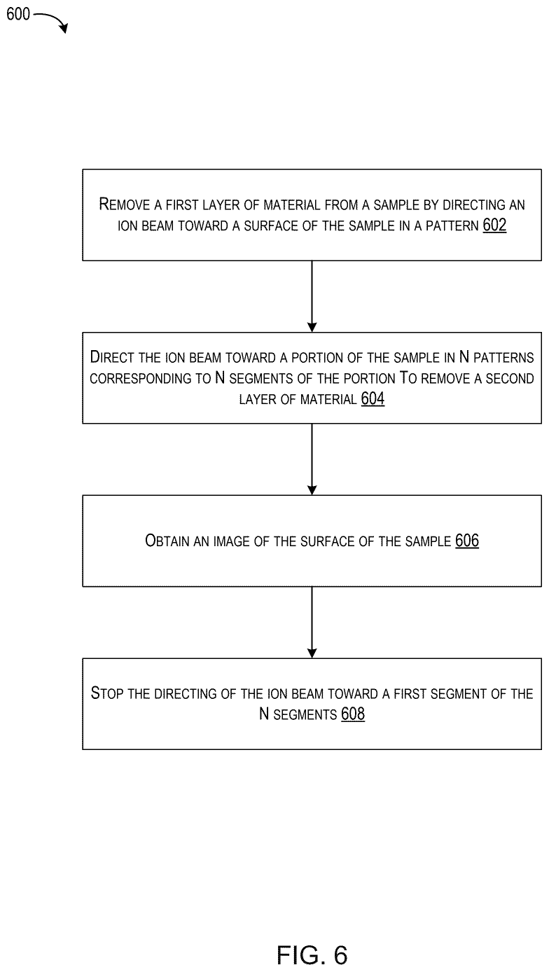

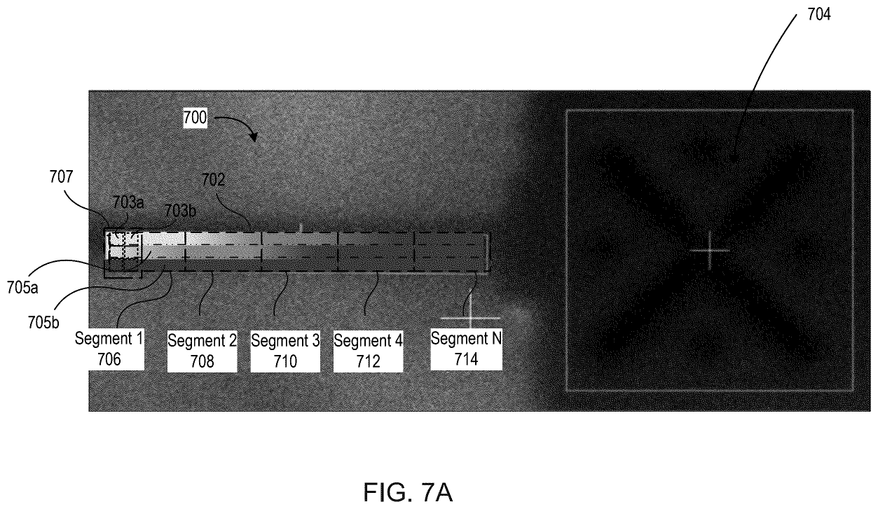

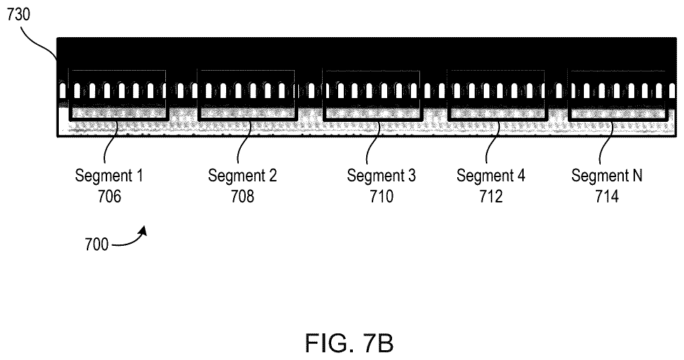

Segmented endpointing may divide the region of interest into n segments which are milled in parallel, as opposed to milling in a single mill pattern. An NN-based endpointing algorithm may determine when to stop patterning within each segment based on the appearance of the sample. For example, an endpointer may determine when to stop milling within each segment and the number of slices completed by each segment indicates the amount of bending which is compensated for in the final lamella. The number of slices may be converted to distance using the endpointers and then converted to the cutface angle when taking the region of interest width into consideration. Another way to implement segmented endpointing includes a gradient-based approach, where the gradient-based approach includes using a single mill pattern that enables gradients in the applied dose between the endpoint segment regions, thereby reducing or eliminating any discontinuities between segments and/or within segments. Rather than employing discrete mill patterns which may be stopped at different times, various embodiments use a single mill pattern that permit adjusting the relative dose of the individual pixels within each patterning line. Embodiments described herein advantageously enable automated, gradient-based endpointing lamella preparation workflows to compensate for lamella warping during TEM lamella thinning in a way that produces a more uniform final finish on the lamella surface and avoids sudden jumps or discontinuities in lamella thickness which are undesirable. Segmented endpointing is shown in FIGS. 5A, 5B, and 6, while “gradient-based segmented endpointing is shown in FIGS. 7, 8, and 9. Embodiments of automated lamella preparation as described herein provide a uniform final finish by applying a continuous gradient in dose informed by the segmented endpointing algorithm to dynamically adjust how much ion dose the lamella face receives along its lateral axis, thereby ensuring a more even and uniform thickness across the entire lateral dimension of the lamella.

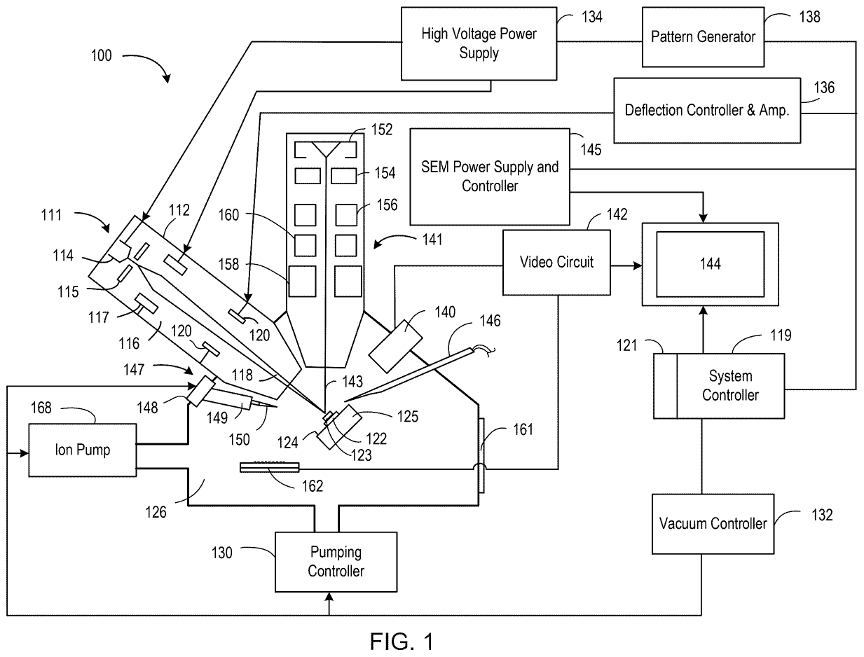

FIG. 1 is a schematic diagram of an example dual beam system 100 for preparing samples using segmented or gradient-based endpointing, according to some embodiments. System 100 may be used to implement the endpointing techniques discussed herein. In some embodiments, the system 100 will perform sample milling and endpoint detection, including segmented endpoint detection. However, in other embodiments, the milling algorithms may be performed by a computing system coupled to system 100, such as at a user's desk or a cloud-based computing system. In either embodiment, the determination of milling endpoint may be provided to system 100 for automatic milling control to ensure that the surface of the thinned lamella is correctly obtained. While an example of suitable hardware is provided below, the invention is not limited to being implemented in any particular type of hardware.

An electron column 141, along with power supply and control unit 145, is provided with the dual beam system 100. An electron beam 143 is emitted from a cathode 152 by applying voltage between cathode 152 and an anode 154. Electron beam 143 is focused to a fine spot by means of a condensing lens 156 and an objective lens 158. Electron beam 143 is scanned two-dimensionally on the specimen by means of a deflector 160. Operation of condensing lens 156, objective lens 158, and deflector 160 is controlled by power supply and control unit 145.

Electron beam 143 can be focused onto substrate 122, which is on stage 125 within lower chamber 126. Substrate 122 may be located on a surface of stage 125 or on TEM sample holder 124, which extends from the surface of stage 125.

When the electrons in the electron beam strike substrate 122, secondary electrons are emitted. These secondary electrons are detected by a charged particle detector 140. In some embodiments, STEM detector 162, located beneath the TEM sample holder 124 and the stage 125 collects electrons that are transmitted through the sample mounted on the TEM sample holder.

System 100 also includes FIB system 111 which comprises an evacuated chamber having an ion column 112 within which are located an ion source 114 and focusing components 116 including extractor electrodes and an electrostatic optical system. The axis of focusing column 116 may be tilted, 52 degrees for example, from the axis of the electron column 141. The ion column 112 includes an ion source 114, an extraction electrode 115, a focusing element 117, deflection plates 120, which operate in concert to form focused ion beam 118. Focused ion beam 118 passes from ion source 114 through focusing components 116 and between electrostatic deflection means schematically indicated at 120 toward substrate 122, which may comprise, for example, a semiconductor wafer positioned on movable stage 125 within lower chamber 126. In some embodiments, a sample may be located on TEM grid holder 124, where the sample may be a chunk extracted from substrate 122. The chunk may then undergo further processing with the FIB to form a final lamella of a desired thickness in accordance with techniques disclosed herein.

Stage 125 can move in a horizontal plane (X and Y axes) and vertically (Z axis). Stage 125 can also tilt and rotate about the Z axis. In some embodiments, a separate TEM sample stage 124 can be used. Such a TEM sample stage will also preferably be moveable in the X, Y, and Z axes as well as tiltable and rotatable. In some embodiments, the tilting of the stage 125/TEM holder 124 may be in and out of the plane of the ion beam 118, and the rotating of the stage is around the ion beam 118. As used herein to illustrate the disclosed techniques, such relationship will be maintained when discussing rotation and tilting of a sample. Of course, the opposite definitions could be used but would still fall within the contours of the present disclosure.

A door 161 is opened for inserting substrate 122 onto stage 125. Depending on the tilt of the stage 124/125, the Z axis will be in the direction of the optical axis of the relevant column. For example, during a data gathering stage of the disclosed techniques, the Z axis will be in the direction, e.g., parallel with, the FIB optical axis as indicated by the ion beam 118. In such a coordinate system, the X and Y axis will be referenced from the Z-axis. For example, the X-axis may be in and out of the page showing FIG. 1, whereas the Y-axis will be in the page, all while all three axes maintain their perpendicular nature to one another.

An ion pump 168 is employed for evacuating neck portion. The chamber 126 is evacuated with turbomolecular and mechanical pumping system 130 under the control of vacuum controller 132. The vacuum system provides within chamber 126 a vacuum of between approximately 1×10⁻⁷ Torr and 5×10⁻⁴ Torr. If an etch assisting, an etch retarding gas, or a deposition precursor gas is used, the chamber background pressure may rise, typically to about 1×10⁻⁵ Torr.

The high voltage power supply provides an appropriate acceleration voltage to electrodes in focusing column 116 for energizing and focusing ion beam 118. When it strikes substrate 122, material is sputtered, that is physically ejected, from the sample. Alternatively, ion beam 118 can decompose a precursor gas to deposit a material.

High voltage power supply 134 is connected to ion source 114 as well as to appropriate electrodes in ion beam focusing column 116 for forming an approximately 1 keV to 60 keV ion beam 118 and directing the same toward a sample. Deflection controller and amplifier 136, operated in accordance with a prescribed pattern provided by pattern generator 138, is coupled to deflection plates 120 whereby ion beam 118 may be controlled manually or automatically to trace out a corresponding pattern on the upper surface of substrate 122. In some systems the deflection plates are placed before the final lens, as is well known in the art. Beam blanking electrodes (not shown) within ion beam focusing column 116 cause ion beam 118 to impact onto blanking aperture (not shown) instead of substrate 122 when a blanking controller (not shown) applies a blanking voltage to the blanking electrode.

The ion source 114 typically provides an ion beam based on the type of ion source. In some embodiments, the ion source 114 is a liquid metal ion source that can provide a gallium ion beam, for example. In other embodiments, the ion source 114 may be plasma-type ion source that can deliver a number of different ion species, such as oxygen, xenon, and nitrogen, to name a few. The ion source 114 typically is capable of being focused into a sub one-tenth micrometer wide beam at substrate 122 or TEM grid holder 124 for either modifying the substrate 122 by ion milling, ion-induced etching, material deposition, or for the purpose of imaging the substrate 122.

A charged particle detector 140, such as an Everhart-Thornley detector or multi-channel plate, used for detecting secondary ion or electron emission is connected to a video circuit 142 that supplies drive signals to video monitor 144 and receiving deflection signals from a system controller 119. The location of charged particle detector 140 within lower chamber 126 can vary in different embodiments. For example, a charged particle detector 140 can be coaxial with the ion beam and include a hole for allowing the ion beam to pass. In other embodiments, secondary particles can be collected through a final lens and then diverted off axis for collection.

A micromanipulator 147 can precisely move objects within the vacuum chamber. Micromanipulator 147 may comprise precision electric motors 148 positioned outside the vacuum chamber to provide X, Y, Z, and theta control of a portion 149 positioned within the vacuum chamber. The micromanipulator 147 can be fitted with different end effectors for manipulating small objects. In the embodiments described herein, the end effector is a thin probe 150.

A gas delivery system 146 extends into lower chamber 126 for introducing and directing a gaseous vapor toward substrate 122. For example, iodine can be delivered to enhance etching, or a metal organic compound can be delivered to deposit a metal.

System controller 119 controls the operations of the various parts of dual beam system 100. Through system controller 119, a user can cause ion beam 118 or electron beam 143 to be scanned in a desired manner through commands entered into a conventional user interface (not shown). Alternatively, system controller 119 may control dual beam system 100 in accordance with programmed instructions stored in a memory 121. In some embodiments, dual beam system 100 incorporates image recognition software to automatically identify regions of interest, and then the system can manually or automatically extract samples in accordance with the invention. For example, the system could automatically locate similar features on semiconductor wafers including multiple devices and take samples of those features on different (or the same) devices.

In operation in accordance with the techniques disclosed herein, system 100 images a working surface (e.g., a cutface) of a sample 123, the sample 123 being a chunk previously removed from a substrate. The chunk, which may be about 1 μm in thickness, may be attached to TEM holder 124 in this example. As used herein, the working surface is a side surface of the chunk, the chunk needing to be thinned into a final lamella thickness. The sample 123 may include structures that should be aligned/oriented to the ion beam 118, such as in terms of rotation and/or tilt, so that during the final lamella formation, structures that require subsequent imaging are not removed. The image of the newly exposed surface can be acquired using either the electron column 141 or the FIB 111.

Layers of sample 123 can be removed from the working surface. The removal of a layer may be performed using FIB milling or ion induced etching using a gas precursor. Layers can be removed in smaller “slices” according to certain embodiments, in which slices of about 1 nm to 5 nm are removed sequentially. After the slice is removed, the newly exposed surface is imaged. The process of image acquisition and slice removal may be repeated for 25, 50, 75, or 100 times, but any other number of slices are contemplated herein. The working surface of the lamella can show structures, such as lines of devices including FETs, which are desired to be imaged and/or analyzed.

The removal of a layer of material from the sample 123 can be done by directing the FIB 111 toward a portion of the sample 123 in a pattern. For example, the ion beam may raster over the surface of the sample 123 in the portion, removing the desired layer. As described in more detail below, the system controller 119 can be configured to direct the ion beam over multiple portions of the sample 123 in a pattern corresponding to each portion. For example, the sample 123 can be divided into N segments, and the ion beam directed over each segment in a raster. The layer of material can then be removed from the sample 123 in each segment in sequence or in parallel. The images of the working surface as the material is removed can be used to determine the endpoint of the milling process with the FIB 111.

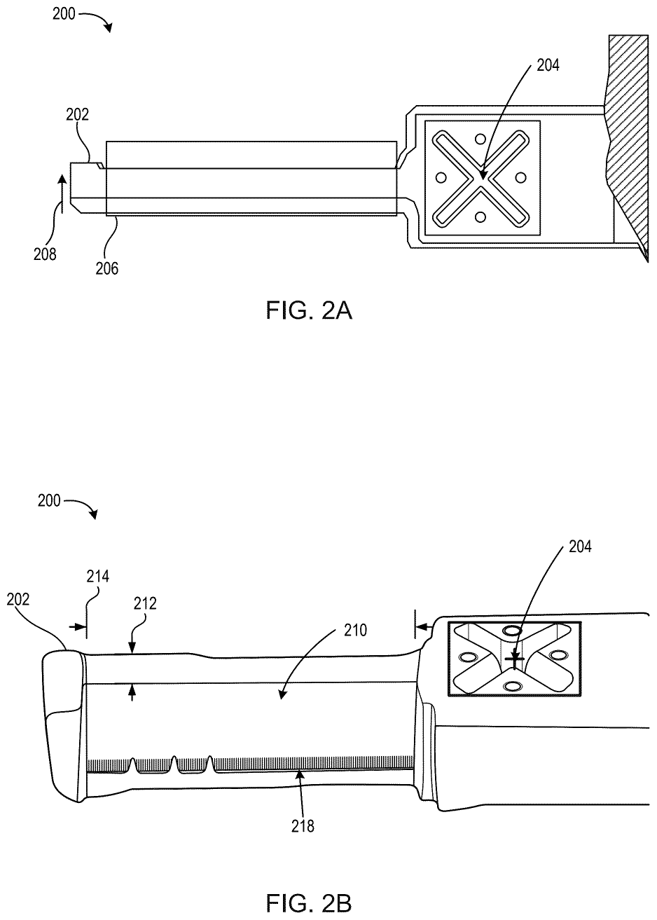

Accordingly, segmented, or gradient-based endpointing may be implemented in dual beam system 100 for preparing samples. For example, the FIB 111 may be directed toward the sample 123 in a segmented manner as described in further detail with respect to FIGS. 2A-6 or the FIB 111 may be directed toward the sample 123 providing a gradient-based dose as described in further detail with respect to FIGS. 7A-9. Images of the sample 123 may be obtained throughout either process using the using either the electron column 141 or the FIB 111.

FIG. 2A is a diagram illustrating a view of a sample 200 for preparation using a dual beam charged particle microscope, according to some embodiments. The dual beam charged particle microscope can be an example of the system 100 described above with respect to FIG. 1.

The view depicted in FIG. 2A shows the “top” view of a lamella 202 formed from the sample 200 via an initial formation technique, for example a cut and lift out technique. The portion of the sample 200 at the right includes a fiducial 204 used to help guide the initial formation of the lamella 202. The material of the sample 200 near the fiducial 204 is typically not of interest in the analysis and forms a structural component of the lamella 202 for handling in the dual beam charged particle microscope. For example, the sample 200 may be attached to TEM holder 124 of FIG. 1 via material to the right of the fiducial 204.

The lamella 202 can be thinned via FIB milling. During thinning, an ion beam may be directed toward a portion 206 of the lamella 202. The portion 206 may include a central region of the lamella 202 that does not include the outer edge of the sample 200. Thus, during thinning, the outer edge of the sample 200 may not be thinned. The thinning of the lamella 202 may proceed in the direction 208 indicated by the arrow in FIG. 2A. Thus, layers of material from the sample 200 from the “bottom” edge of the portion 206. Because the ion beam may be aligned substantially parallel to the working surface of the lamella 202, the ion beam may be directed into/out from the page with respect to the view shown in FIG. 2A. In some embodiments, the direction 208 of the thinning may be reversed depending on the type of sample 200 and the milling techniques employed (e.g., backside thinning).

Thinning of the lamella 202 can proceed in several steps in which a layer of material is removed at each step. For example, a first layer of material can be removed from the lamella 202 within the portion 206 shown in FIG. 2A. Subsequently, a second layer (or third, or suitable number of additional layers) can be removed from an additional portion of the lamella 202. The energy of the ion beam can be different for the removal of each layer. For example, a first layer can be removed using a first energy of the ion beam (e.g., 30 kV) while a second layer can be removed using a second energy of the ion beam (e.g., 2 kV). The additional portion of the lamella 202 can be located in a central region of the lamella 202 smaller than the portion 206. The result of the sequential thinning operations can result in a “stair-step” pattern of thinner regions of the lamella with a central portion thinned to the desired thickness.

FIG. 2B is a diagram illustrating another view of the sample 200 of FIG. 2A including structures 218 of the sample 200, according to some embodiments. With respect to the view of FIG. 2A, FIG. 2B shows the cutface 210 of the lamella 202 on the side defined by the direction 208.

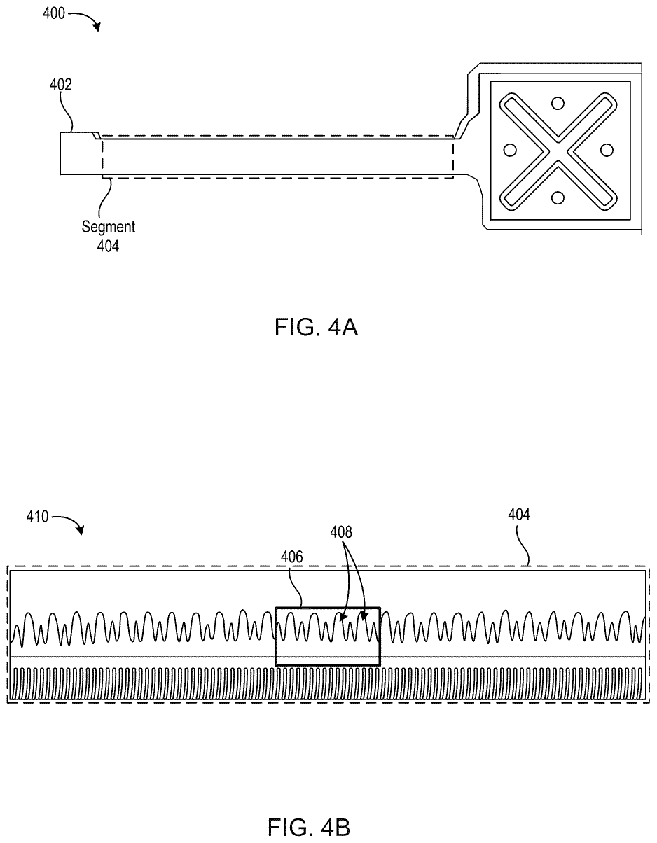

For a given sample 200, the lamella 202 can have a thickness 212 and a length 214 defined in the direction transverse to the direction 208 and the thickness 212. The thinning operations can be configured to reduce the thickness 212 to a desired thickness. As described briefly above, the initial thickness 212 of a lamella 202 after cut and lift out can be on the order of 1 μm, while the length of the lamella may be about 3 μm or greater. The lamella 202 can be thinned by removing layers of material until the thickness 212 is about 100 nm. This first thinning operation can be done using a single endpoint for the lamella 202 (described in more detail below with respect to FIGS. 4A and 4B). The lamella 202 can then be thinned further by removing additional layers of material until the thickness 212 is less than about 15 nm (e.g., 10 nm). The additional thinning operation can be done using segmented endpointing with multiple segments for milling the lamella 202, each having a corresponding endpoint. As the lamella 202 is thinned, it may exhibit a warping or bending in directions transverse to its length 214. For example, a lamella 202 of thickness less than about 100 nm may bend slightly in the direction 208 of the thinning, so that the left edge of the lamella 202 (with respect to the view of FIG. 2B) is displaced further in the direction 208 than the right edge of the lamella 202.

The sample 200 can include multiple devices or other structures of interest. The devices can be FETs (e.g., FinFETS) or other semiconductor devices (e.g., power transistors, etc.). Portions of the devices can appear at the working surface of the sample 200 as a variety of structures. As depicted in FIG. 2B, various structures, including structures 218, can be seen at the cutface 210 of lamella 202. The manufacturing of the devices typically results in a line of repeating device elements visible on the cutface 210. For example, the channel structures of FETs and the associated gate fins and oxide layers can appear as repeating small-scale structures 218. Larger scale structures (e.g., vias) can also appear at the cutface 210. Within the sample 200, additional device lines may be formed parallel to the devices shown at the cutface 210 but deeper within the sample volume. Thus, a device line with structures similar to structures 218 may be located behind the devices visible at the cutface 210. As the lamella 202 is thinned, the material of the devices at the surface can be removed, revealing the devices and associated structures deeper within the sample 200.

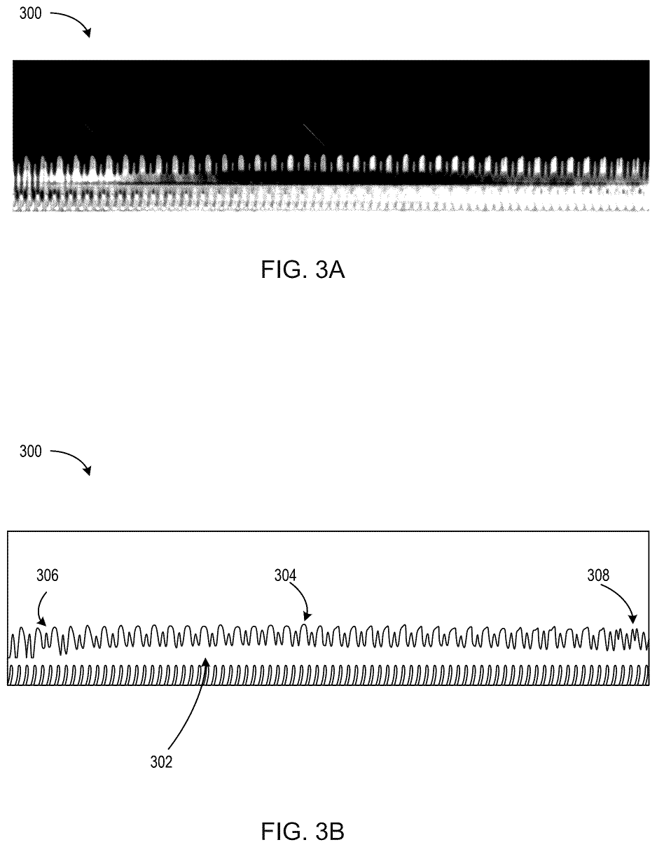

FIG. 3A is an image of a cutface 300 of a sample showing a plurality of structures, according to some embodiments. The image may be obtained from a lamella (e.g., lamella 202 of FIG. 2) using the electron beam of a dual beam charged particle microscope, for example the system 100 of FIG. 1. In some embodiments, the ion beam may be used for imaging the cutface 300 of the sample. The lamella shown in FIG. 3A has been thinned to a thickness of less than about 100 nm using a single endpoint. As shown in FIG. 3A, the cutface 300 can include a line of structures associated with a plurality of semiconductor devices. For example, the line of structures may be the fins of a FinFET.

FIG. 3B is a diagram of the cutface 300 of FIG. 3A, identifying various structures 302 of the sample, according to some embodiments. The structures 302 can be characterized by repeated “peaks” for a line of similar devices along the length of the lamella. Visible in both the diagram of FIG. 3B and the image of FIG. 3A are structures 304 at the center of the lamella, and structures 306 and structures 308 near the edges of the lamella. The “peaks” of the structures 306 and structures 308 are doubled, indicating the imaging of device structures in front of and/or behind the device line associated with the structures 304. Such distortion of the image for the structures 306 and 308 indicates that the thinning process at the edges of the lamella either removed too much or too little material, so that the structures 306 and structure 308 include portions of the device line corresponding to structures 304 as well as a device line in front of/behind the device line of interest in the lamella. In addition to the distorted “peaks” shown in FIG. 3B, other distortions can include occlusions of features of interest in the sample by features closer to the surface. For instance, in the example of a FET, the inaccuracy of the milling endpoint at the edges of the lamella can be caused by the warping of the lamella along its length.

FIG. 4A is a diagram illustrating milling a sample 400 using one pattern, according to some embodiments. The sample may be an example of the sample 200 described above with respect to FIG. 2. The sample 400 can include a lamella 402 to be thinned. The thinning can occur in a segment 404 of the of the lamella 402 using an ion beam of a dual beam charged particle system (e.g., system 100 of FIG. 1).

FIG. 4B is a diagram illustrating the cutface 410 of the sample 400 of FIG. 4A with the milling stopped based on a single endpoint 406, according to some embodiments. During the thinning operation, the ion beam can be configured to remove a layer of material from the lamella 402 in a pattern over the segment 404.

As the material in the layer is removed, images of the cutface 410 can be obtained showing one or more structures of interest within the sample 400. As shown in FIG. 4B, the structures 408 can be repeated “peaks” of device features, for example, gate fins of FETs in a device line. The endpoint 406 can be a representation of expected structures in the device line and may be characterized by one or more parameters of the structures including dimensions (e.g., width, height), pitch (e.g., separation from one feature to the next), shape (e.g., square or “rounded” profile), and the like. For the example of a line of FinFETs, the structures may be the repeated fins separated by a characteristic pitch. The endpoint 406 can then define the expected dimensions, shape, pitch, or other parameters of the devices of interest in the lamella. Comparing the endpoint 406 to the image can include image correlation techniques, for example, cross correlation, sum of squared differences, mutual information, and the like.

The dual beam charged particle microscope can be configured to automatically stop the milling process when the structures 408 visible in an image of the cutface 410 of the lamella 402 match the endpoint 406. For example, as material is removed, the devices in the sample 400 may be visible at the cutface 410. The dual beam charged particle microscope can be configured to obtain an image of the cutface 410 including the structures 408. The dual beam charged particle microscope can then compare the image to the endpoint 406. If the structures 408 match the expected structures in the endpoint 406, then the dual beam charged particle microscope can stop milling. The endpoint 406 can correspond to a small portion of the devices in the sample. For example, the endpoint 406 may correspond to a central portion of the lamella 402.

FIG. 4B shows endpointing using a single segment 404 and single endpoint 406. Such single segment endpointing can be used for initial thinning operations on the lamella 402 when the thickness of the lamella 402 is large enough (e.g., greater than about 100 nm) to not be susceptible to warping. The single segment endpointing can be used in conjunction with segmented endpointing described below with respect to FIGS. 5A and 5B.

FIG. 5A is a diagram illustrating milling a sample 500 using N patterns for N segments 504-512, according to some embodiments. The sample 500 may be an example of sample 200 of FIG. 2. In some embodiments, sample 500 may be the same as sample 400 of FIGS. 4A and 4B after an initial thinning operation using a single segment and single endpoint. As shown in FIG. 5A, a portion of the lamella 502 can be divided into N segments (e.g., five segments), including segment 1 504, segment 2 506, segment 3 508, segment 4 510, and segment N 512. A dual beam charged particle microscope (e.g., system 100 of FIG. 1) can be configured to direct an ion beam at the lamella 502 in a pattern for each of the segments 504-512. For example, the ion beam can be configured to raster over each segment 504-512 to remove material from the lamella in each segment. The ion beam can be configured to remove the material from the segments 504-512 in parallel, so that a portion of the layer of material is removed from segment 1 504, then a portion of the layer of material from segment 2 506, and so on. In some embodiments, the pattern of the ion beam for each segment can be the same or different as the pattern of the ion beam for the other segments.

FIG. 5B is a diagram illustrating the cutface 530 of the sample of FIG. 5A with the milling stopped in segments 504-512 according to N endpoints 514-522, according to some embodiments. As material is removed from the lamella 502, images of the cutface 530 can be obtained by the dual beam charged particle microscope. Each image can include the portions of the lamella 502 corresponding to the segments 504-512, showing the device structures within that portion of the lamella 502. For example, segment 508 can include structures 524. Each segment 504-512 can have a corresponding endpoint 514-522. For instance, segment 1 504 can correspond to endpoint 514, segment 2 506 can correspond to endpoint 516, and so on. The dual beam charged particle microscope can be configured to compare the images of the segments 504-512 to the endpoints 514-522 to control and stop the milling process. Each of endpoints 514-522 can be compared to a central portion of the corresponding segments 504-512. The location within each segment for comparison with the endpoint can vary. For example, the endpoint can be compared to a portion of the bottom of the segment.

The milling of each segment can be controlled separately to achieve the appropriate milling endpoint for the segment. When a segment reaches the desired end point (based on the comparison of an image of the segment with the corresponding endpoint), the pattern of the ion beam in that segment can be stopped, while the ion beam continues to remove material from the other segments. For example, the dual beam charged particle microscope can obtain an image of the cutface 530 including segment 3 508 and showing structures 524. When the structures 524 match the expected structures in the corresponding endpoint 518, the milling of segment 3 508 can be stopped, while the milling of segment 1 504, segment 2 506, segment 4 510, and segment N can continue. Thus, once a segment of the lamella 502 is milled to the desired thickness based on a comparison of an image of the segment with the corresponding endpoint, the milling of that segment can stop.

In some embodiments, the number of segments N can be more or fewer than depicted in FIGS. 5A and 5B. For example, the number of segments can be 2, 3, 4, 6, or 10 or more. The number of segments N can be determined based on the length (e.g., length 214 of FIG. 2) of the lamella 502. For example, a longer lamella may be thinned using a larger number of segments than a shorter lamella. The number of segments N can also be determined based on the thickness (e.g., thickness 212 of FIG. 2) of the lamella. In addition, the number of segments used for the removal of one layer of material from the sample 500 can be different than the number of segments used for the removal of another layer of material from the sample 500. For example, a first layer of material can be removed using a single segment and single endpoint until a portion of the lamella 502 is about 100 nm thick, a second layer of material can be removed using three segments and three endpoints until a second portion of the lamella 502 is about 50 nm thick, and a third layer of material can be removed using five segments and five endpoints until a third portion of the lamella 502 is less than about 15 nm thick. It is contemplated that various combinations of number of segments and number of layers removed can be used when thinning the lamella 502 to a suitable thickness. In some embodiments, each subsequent layer of material removed can include milling segments for smaller portion of the segment milled to remove the previous layer. For example, a first layer can be milled within a single segment, then a second layer can be milled for five segments that span a slightly smaller portion of the single segment. In some embodiments, the ion beam can have a different characteristic beam energy for each layer of material removal. For example, the ion beam can have a beam energy of 30 kV when removing the first layer of material and have a beam energy of 2 kV when removing the second layer and the third layer.

In some embodiments, segments can be the same size or different sizes along the length of the lamella 502. As shown in FIGS. 5A and 5B, the segments 504-512 divide the portion of the lamella 502 into five equal length segments. In some examples, the segments can have unequal widths. In particular, the segments closest to the edges of the lamella 502 may be larger than the segments in the center of the lamella 502 to account for a width of the ion beam. For example, segment 1 504 and segment N 512 may be larger than the width of segments 506-510 by a value corresponding to the width of the ion beam. In some embodiments, the segments can be arranged adjacent to one another over the portion of the lamella 502 being thinned. In other embodiments, a portion of each segment may overlap with an adjacent portion.

FIG. 6 is a flow diagram of an example process 600 for operating a dual beam charged particle microscope system to prepare a sample using a plurality of endpoints, according to some embodiments. The dual beam charged particle microscope system may be an example of other charged particle microscope systems described herein, including system 100 of FIG. 1. The charged particle microscope system can include a computer system (e.g., system controller 119 of FIG. 1) configured to carry out the operations of process 600. For example, a computer system may be configured to adjust the parameters of the electron beam (e.g., accelerating potential, beam focus parameters, beam current, beam deflection, etc.), the ion beam (e.g., accelerating potential, beam focus parameters, ion species selection, beam current, etc.), the milling patterns (e.g., raster), the number of segments (e.g., 1, 5, N), the scanning/imaging parameters for SEM mode (e.g., sweep time, dwell time, etc.), activation/deactivation of both the electron beam and the ion beam (or additional beams, e.g., laser beams, present in multiple beam systems), detector settings (e.g., biasing voltage, collector grid voltage, etc.), and other suitable parameters for the operation of such a microscopy system. The computer system may also be configured to analyze images obtained using the microscopy system to identify structures and/or features of interest in a sample being milled and compare those structures with desired endpoints to control the milling according to the operations of process 600. The sample may be an example of any of the samples described herein, including sample 200 of FIG. 2 and sample 400 and sample 500 of FIGS. 4A and 5A.

At block 602a first layer of material from a sample is removed by directing an ion beam toward a surface of the sample in a pattern. The first layer can be removed from a segment of the sample, for example segment 404 of FIG. 4. The ion beam can be directed toward the surface of the sample in a raster pattern or other suitable pattern to remove material from the surface. The surface of the sample from which material is removed may be referred to as the working surface or cutface (e.g., cutface 410 of FIG. 4B) of the sample. The beam path of the ion beam may be substantially parallel to the cutface.

At blocks 604-608, a second layer of material is removed from the segment. The second layer can be removed so that the thickness of a portion of the segment is reduced. For example, a portion of segment 404 of FIG. 4 can be further thinned to reduce the thickness of lamella 402. At block 604, the ion beam is directed toward the portion of the segment in N patterns corresponding to N segments of the portion (e.g., segments 504-512 of FIG. 5A). The N segments can each be smaller than the segment for the first layer (e.g., the N segments may span a smaller portion of the lamella than the segment for the first layer).

At block 606, dual beam charged particle microscope system obtains an image of the surface of the sample. The image can show a first segment of the N segments of the sample. For example, the image can be an image of the cutface 530 shown in FIG. 5B. The image can show one or more structures of the sample for each segment. In some embodiments, the image can show a view of a first structure of a plurality of structures (e.g., structures 524 of FIG. 5B) within the first segment (e.g., segment 3 508 of FIG. 5B). In some embodiments, the image can be obtained using an electron beam of the dual beam charged particle microscope system. The electron beam can be directed at the surface of the sample to image the cutface. In some embodiments, the ion beam may be used to obtain the image.

At block 608, dual beam charged particle microscope system stops the directing of the ion beam toward the first segment of the N segments. Stopping the ion beam for the first segment may be based on the image. In some embodiments, stopping the directing of the ion beam can include comparing the image to an endpoint to the first segment of the sample. The endpoint can be characterized by a desired structure having one or more parameters. For example, the desired structure can be an ideal device feature (e.g., gate fin of a FET) for a particular manufacturing specification of the devices in the sample. The desired structure can then include dimensions, profile, pitch, or other suitable parameters for comparison in image analysis. In some embodiments, comparing the image to the endpoint can include comparing the view of the first structure to the desired structure of the endpoint. If the parameter(s) (e.g., dimensions, profile, pitch, etc.) match (e.g., are equal within some desired tolerance), then the ion beam can be stopped for the first segment.

In some embodiments, removing the second layer of material can also include continuing to direct the ion beam toward the remaining segments, obtaining an additional image of the surface of the sample, and then stopping the ion beam for a second segment of the remaining segments based on a comparison of the image and an additional endpoint. In this way, each segment of the N segments can be thinned until each segment reaches the desired endpoint. The lamella can then have the desired thickness across its length that is suitable for subsequent use (e.g., as a sample for scanning transmission electron microscopy). In some embodiments, the endpoints for each segment may be the same or may be different from one another.

In some embodiments, additional layers of material can be removed according to the operations of blocks 604-608 using more, fewer, or the same number of segments. For example, a third layer of material can be removed from the segment so that the thickness of an additional portion of the segment is further reduced. The ion beam can be directed toward the additional portion in M patterns, an additional image of the surface of the sample can be obtained, and the ion beam can be stopped for a second segment of the M segments based on a comparison of the additional image with an endpoint corresponding to the second segment.

In some embodiments, the ion beam can be set to different energies for each layer removed. For example, the first layer can be removed with the ion beam set to a first energy (e.g., 30 kV) and the second layer can be removed using the N segments with the ion beam set to a second energy (e.g., 2 kV) different from the first energy.

In some embodiments, the number of segments N can be based in part on the thickness of the sample after the removal of the first layer of material. The number of segments N can also be based on the desired thickness of the sample at the end of the removal of the second layer of material. In various embodiments, N may be a predetermined number, may be based in part on a length (e.g., length 214 of FIG. 2) of the portion of the segment, or may be based in part on a material of the sample.

In some embodiments, the N segments may be adjacent and non-overlapping. In other embodiments, one segment may overlap with a portion of another segment of the N segments. In some embodiments, each segment may have the same width or have different widths. In some embodiments, some of the segments may be wider than the other segments. For example, in some embodiments, a first segment (e.g., segment 1 504 of FIG. 5A) and a final segment (e.g., segment N 512 of FIG. 5A) of the N segments can have an extended width characterized by a default width of the N patterns and a beam width of the ion beam.

Segmented endpointing may divide the region of interest into n segments which are milled in parallel, as opposed to milling in a single mill pattern. An NN-based endpointing algorithm may determine when to stop patterning within each segment based on the appearance of the sample. For example, an endpointer may determine when to stop milling within each segment and the number of slices completed by each segment indicates the amount of bending which is compensated for in the final lamella. The number of slices may be converted to distance using the endpointers and then converted to the cutface angle when taking the region of interest width into consideration. Some discontinuities may be present at segment interfaces (e.g., either too much or too little dose is applied at the segment transitions). Other discontinuities may include the appearance of fringes and other artifacts and other imaging artifacts in the TEM images.

Embodiments of the present disclosure provide systems and methods for performing thinning using a single mill pattern that enables gradients in the applied dose between the endpoint segment regions, thereby reducing or eliminating any discontinuities between segments and/or within segments. Rather than employing discrete mill patterns which may be stopped at different times, various embodiments use a single mill pattern that permit adjusting the relative dose of the individual pixels within each patterning line based on the feedback from the SEM image-based neural network used for segmented endpointing. Accordingly, all portions of the region of interest may continue to receive ion dose throughout the thinning process and avoid any uneven thinning at boundaries between the mill segments. Embodiments described herein advantageously enable automated lamella preparation workflows to compensate for lamella warping during TEM lamella thinning in a way that produces a more uniform final finish on the lamella surface and avoids sudden jumps or discontinuities in lamella thickness which are undesirable.

FIGS. 7A and 7B are diagrams illustrating milling a sample using gradient-based segmented endpointing. FIG. 7A illustrates an FIB view of a sample 700 for preparation using a dual beam charged particle microscope, according to some embodiments. The dual beam charged particle microscope can be an example of the system 100 described above with respect to FIG. 1. FIG. 7A illustrates using a single pattern with a continuous gradient in dose as informed by the segmented endpointing algorithm to dynamically adjust how much ion dose the lamella 702 receives at each dwell point, e.g., scan pixel, along its lateral axis, thereby varying an amount the sample is milled at each dwell point across the face of the sample, where the variations in milling is based on the image analysis, e.g., topography changes, of the lamella face. By varying the milling, the technique disclosed herein ensures or causes a more even and uniform thickness across the entire lateral dimension of the lamella 702 to be obtained.

The view depicted in FIG. 7A shows the “top” view of a lamella 702 formed from the sample 700 via an initial formation technique, for example a cut and lift out technique. The portion of the sample 700 at the right includes a fiducial 704 used to help guide the initial formation of the lamella 702. The material of the sample 700 near the fiducial 704 is typically not of interest in the analysis and forms a structural component of the lamella 702 for handling in the dual beam charged particle microscope. For example, the sample 700 may be attached to TEM holder 124 of FIG. 1 via material to the right of the fiducial 704.

FIG. 7A further illustrates milling the sample 700 using N patterns for N segments 706-714, according to some embodiments. As shown in FIG. 7A, the lamella 702 can be divided into N segments (e.g., five segments), including segment 1 706, segment 2 708, segment 3 710, segment 4 712, and segment N 714. Each segment includes at least a portion of a raster line 705 (including raster line 705a and raster line 705b as shown in FIG. 7A), in some embodiments. Each raster line 705 is formed by one or more pixels 703 (including pixel 703a and pixel 703b as shown in FIG. 7A). Furthermore, each segment may include one or more sections 707. A section 707 may include one or more pixels 703 from the same or different raster lines 705. For example, section 707 includes 3 pixels from 3 raster lines (e.g., for 6 pixels total) as shown in FIG. 7A, although the number of pixels, portions of raster lines, raster lines, etc., may vary according to embodiments of the present disclosure. In some embodiments, at least two sections 707 of the segment may be analyzed using imaging methods, to be described in further detail below, to determine a variation in material removal between the at least two sections of the segment. Each of the at least two sections is mapped to a set of pixels of the pattern. The variation in material removal may be a difference in thickness between the at least two sections, according to at least some embodiments.

A dual beam charged particle microscope (e.g., system 100 of FIG. 1) can be configured to direct an ion beam at the lamella 702 in various patterns to mill the lamella 702 within each of the segments 706-714. For example, the ion beam can be configured to raster over each segment 706-714 to remove material from the lamella 702 in each segment. The milling of each segment 706-714 can be performed separately, e.g., segment by segment, or all at once where a raster pattern scans all the way across a plurality of segments in a single line, for example, before starting over. In some examples, the ion beam can be configured to remove the material from the segments 706-714 in parallel, so that a portion of the layer of material is removed from segment 1 706, then a portion of the layer of material from segment 2 708, and so on.

According to embodiments of the present disclosure, the dose of the milling is dynamically adjusted (e.g., adjusted during the milling and/or in response to feedback from the system, such as system 100) and delivered to different regions of the lamella by manipulating at least the dwell time at a per-pixel level across the scan line in the pattern based on feedback from an endpointing neural network within defined segments. For example, milling may begin based on the assumption that no bending occurs in the lamella 702 (e.g., the same dose is applied across each of the segments 706-714). After milling a first layer, the segments 706-714 may be imaged and the dose applied to one or more of the segments 706-714 may be dynamically adjusted based at least in part on feedback from the endpointing neural network. According to various embodiments, pixels within each of the segments 706-714 are linked to adjacent pixels such that increasing the dose on one pixel creates a gradient (e.g., with a defined window size) affecting neighboring pixels. As shown in FIG. 7A, a gradient of dosing is applied to the lamella 702. The dosing may be linear or non-linear. In further embodiments, the dosing may be applied as a gradient (e.g., the milling may be performed) until a specific feature or region of interest is visible in imaging of the lamella, to be described in further detail below.

FIG. 7B is a diagram illustrating the cutface 730 of the sample 700 of FIG. 7A with the milling stopped in segments 706-714. As material is removed from the lamella 702, images of the cutface 730 can be obtained by the dual beam charged particle microscope. Each image can include the portions of the lamella 502 corresponding to the segments 706-714, showing the device structures within that portion of the lamella 702.

In some embodiments, the number of segments N can be more or fewer than depicted in FIGS. 7A and 7B. For example, the number of segments can be 2, 3, 4, 6, or 10 or more. The number of segments N can be determined based on the length (e.g., length 214 of FIG. 2) of the lamella 702. For example, a longer lamella may be thinned using a larger number of segments than a shorter lamella. The number of segments N can also be determined based on the thickness (e.g., thickness 212 of FIG. 2) of the lamella 702. Any techniques for determining the number of segments N and the size thereof described herein may be applied to embodiments illustrated in FIGS. 7A and 7B.

In some embodiments, segments can be the same size or different sizes along the length of the lamella 702. As shown in FIGS. 7A and 7B, the segments 706-714 divide the portion of the lamella 702 into five equal length segments. In some examples, the segments can have unequal widths. In particular, the segments closest to the edges of the lamella 702 may be larger than the segments in the center of the lamella 702 to account for a width of the ion beam. For example, segment 1 706 and segment N 714 may be larger than the width of segments 708-712 by a value corresponding to the width of the ion beam. In some embodiments, the segments can be arranged adjacent to one another over the portion of the lamella 702 being thinned. In other embodiments, a portion of each segment may overlap with an adjacent portion.

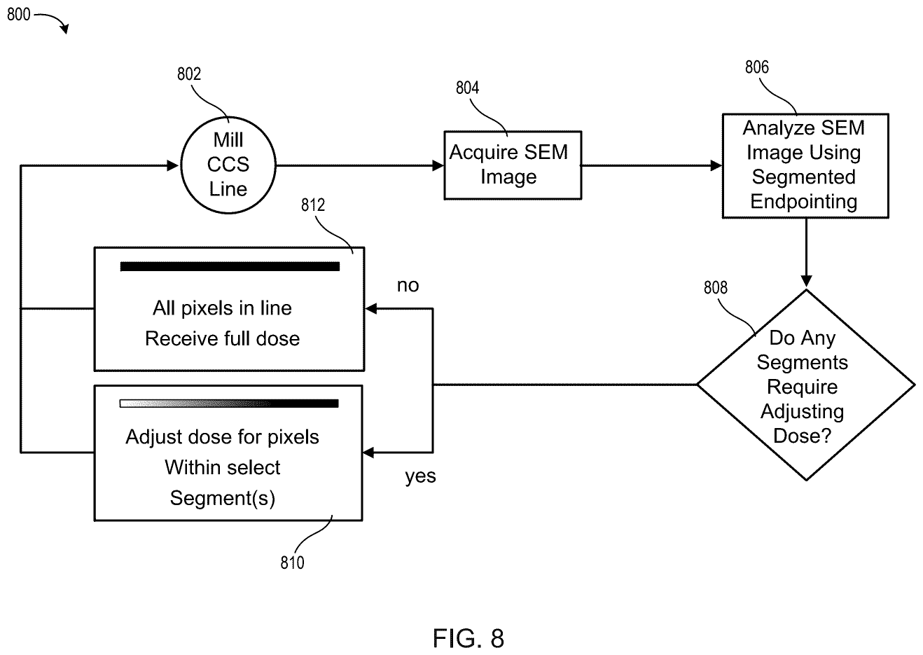

FIG. 8 is a flow diagram of an example process for milling a sample using gradient-based segmented endpointing, according to some embodiments. The process 800 may include more or less operations and/or decision points than those shown in FIG. 8. Operation 802 includes milling a clean cross section (CCS) line. In various embodiments, a first CCS line may be milled where an ion dose is uniformly applied across a length of a lamella. Further CCS lines may include varying or gradient-based ion dosing according to embodiments of the present disclosure, to be discussed in further detail below.

Operation 804 includes acquiring an SEM image. According to various embodiments, at least a portion of the lamella may be imaged in a manner known in the art. Operation 806 includes analyzing the SEM image using segmented endpointing as described in detail above. According to some embodiments, the imaging may be used to determine whether a feature of interest and/or a region of interest is visible in the lamella. Furthermore, the imaging may be used to determine whether and to what extent the dose is modified for the next CCS line.

Decision point 808 may include determining whether any segments require adjusting the dose, as determined by analyzing the imaging in operation 806. Decision point 808 may include determining that there is a variation in thickness between two segments. For example, decision point 808 may include determining that a first segment is significantly thicker than an adjacent second segment. If yes, process 800 proceeds to operation 810 illustrating adjusting the dose for pixel within the selected segment(s). For example, one or more segments may be determined to require an adjusted dose, but other segments may remain at the previous dosage amount. If no, process 800 proceeds to operation 812 illustrating that all pixels in line receive the full (e.g., the previously applied amount of) dose.

Process 800 may proceed through one or more of the foregoing operations until a feature of interest and/or a region of interest is visible in the SEM image or until another predetermined criteria is met. For example, operation 806 may further include analyzing the SEM image to determine whether to stop the process 800 as would be appreciated by one having ordinary skill in the art.

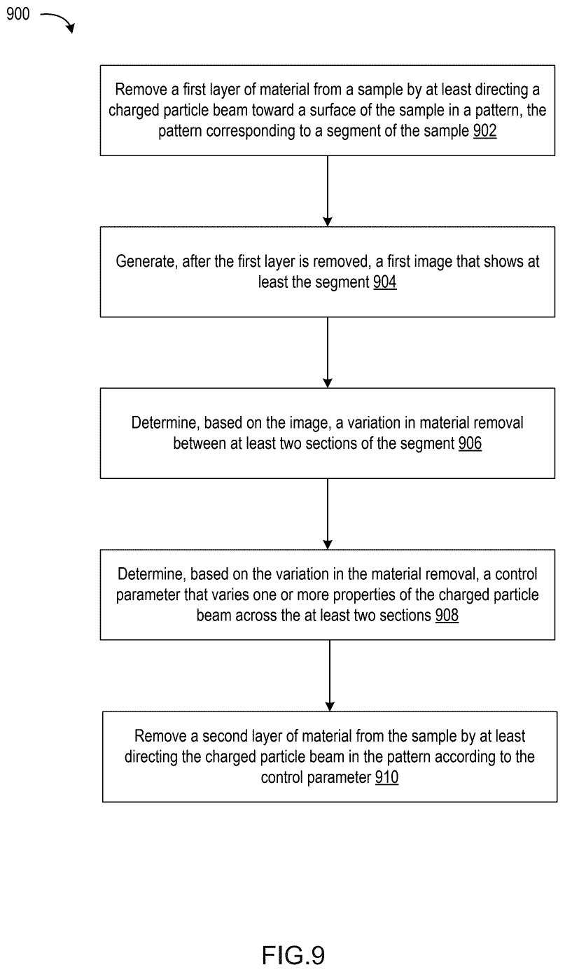

FIG. 9 is a flow diagram of an example process 900 for operating a dual beam charged particle microscope system to prepare a sample using a plurality of endpoints, according to some embodiments. The dual beam charged particle microscope system may be an example of other charged particle microscope systems described herein, including system 100 of FIG. 1. The charged particle microscope system includes a computer system (e.g., system controller 119 of FIG. 1) configured to carry out the operations of process 900. For example, a computer system may be configured to adjust the parameters of the electron beam (e.g., accelerating potential, beam focus parameters, beam current, beam deflection, etc.), the ion beam (e.g., accelerating potential, beam focus parameters, ion species selection, beam current, etc.), the milling patterns (e.g., raster), the number of segments (e.g., 1, 5, N), the scanning/imaging parameters for SEM mode (e.g., sweep time, dwell time, etc.), activation/deactivation of both the electron beam and the ion beam (or additional beams, e.g., laser beams, present in multiple beam systems), detector settings (e.g., biasing voltage, collector grid voltage, etc.), and other suitable parameters for the operation of such a microscopy system. The computer system may also be configured to analyze images obtained using the microscopy system to identify structures and/or features of interest in a sample being milled and compare those structures with desired endpoints to control the milling according to the operations of process 900. The sample may be an example of any of the samples described herein, including sample 200 of FIG. 2 and sample 400 and sample 500 of FIGS. 4A and 5A.

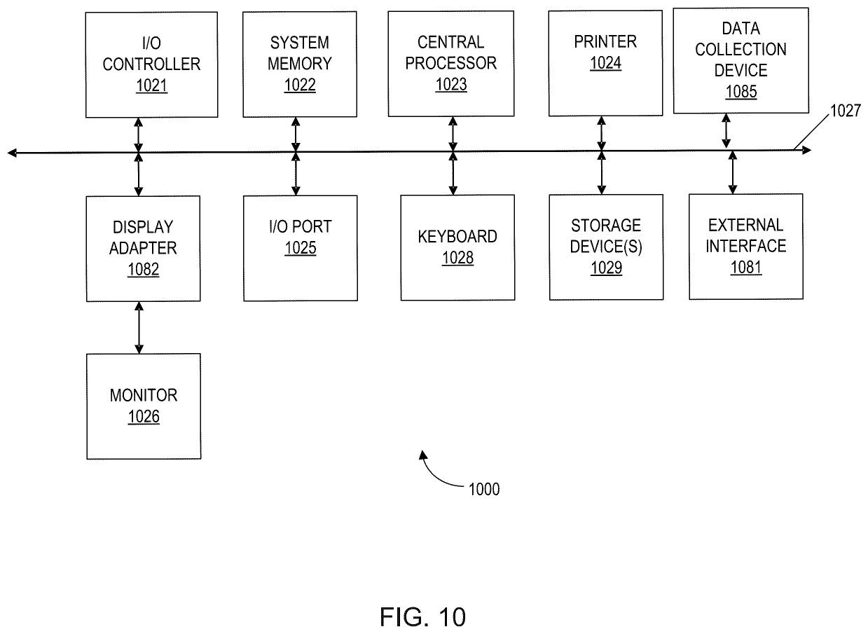

Various embodiments of process 900, including any blocks described herein, may be performed manually or under the control of the computer system described in FIG. 10, to be described in further detail below. Process 900 includes various operations for milling a sample using gradient-based segmented endpointing. Process 900 may include more or fewer operations than those described herein, and various operations may be performed in alternative configurations than those described herein. Process 900 may include block 902. At block 902, process 900 includes removing a first layer of material from a sample by at least directing a charged particle beam toward a surface of the sample in a pattern. The pattern may correspond to a segment of the sample, such as segments 706-714 as shown in FIGS. 7A and 7B.

At block 904, process 900 may include generating, after the first layer is removed, a first image that shows at least the segment. The image may be a SEM image. In other embodiments, the imaging may be performed by any imaging system known in the art. A total number of the sections may be N where N is predefined by a user, for example. Each segment may include one or more sections. Each section may be mapped to one or more pixels. A pixel as described herein may refer to location of the lamella the beam is focused on for a dwell time. A section may extend across the entire segment. Similarly, the segment may extend across the entire lamella.

At block 906, process 900 may include determining, based on the image, a variation in material removal (and resulting lamella thickness) between at least two sections of the segment. The at least two sections are adjacent and non-overlapping according to some embodiments. In other embodiments, it may be advantageous to compare sections that are not adjacent to determine a variation in thickness across the sample. Each one of the at least two sections may have a same width. For example, each one of the at least two sections may have a same initial width but the width of one or more of the at least two sections may be modified according to some embodiments. In various embodiments, each of the at least two sections is mapped to a set of pixels of the pattern. In some embodiments, block 906 may also include determining that the width of at least one of the two sections should be adjusted based at least in part on the image and block 906 may include performing the adjusting.

At block 908, process 900 may include determining, based on the variation in material removal, a control parameter that varies one or more properties of the charged particle beam across the at least two sections. In at least some embodiments, the control parameter varies across at least two pixel sets of the pattern. The control parameter may be one or more of a dosage of the charged particle beam per section of the segment, an energy level of the charged particle beam per section (or pixel) of the segment, a dwell time of the charged particle beam per section of the segment, or a sweep time of the charged particle beam per section of the segment. The control parameter may include any combination of the foregoing parameters or any predetermined combinations of the foregoing parameters. For example, a user may predetermine that varying an energy level includes also varying the dwell time for a particular segment.

In various embodiments, a control parameter is determined based at least in part on the thickness. For example, if a segment is thinner than another one (too much material removal), the determination here can be to adjust the dosage, so the milling removes a thinner layer (e.g., the dosage is relatively lower). Conversely, if a segment is thicker than another one (too little material removal), the determination here can be to adjust the dosage, so the milling removes a thicker layer (e.g., the dosage is relatively higher). According to some embodiments, a hybrid approach can be used, where the dosage may be made, in a same pattern, lower for a thinner segment and higher for a thicker segment.

At block 910, process 900 may include removing a second layer of material from the sample by at least directing the charged particle beam in the pattern according to the control parameter. The removal of the second layer of material may be performed sequentially across sections of the segment. In some embodiments, the control parameter may be varied linearly across sections of the segment. In other embodiments, the control parameter may be varied non-linearly across sections of the segment. The control parameter may be varied in combinations of linear and non-linear variations across the segments, as determined based at least in part on the image analysis in block 906.

Process 900 may further include outputting, by a neural network, an indication of a thickness variance across sections of the segment. For example, determining the control parameter as in block 908 may include adjusting the control parameter based on the indication. Accordingly, process 900 may include outputting, by the neural network, a recommended adjustment for the control parameter. For example, at 906, a neural network (NN) can be used for the image processing. The NN may be pre-trained using labeled segments in training SEM images and known thickness variances (e.g., variations in the average thickness of each segment) shown in such images such that, given a new SEM image, the NN can output a thickness variance prediction. Accordingly, at block 906, the SEM image can be input to the NN that, in response, outputs a prediction of the thickness variance for one or more of the segments.

According to various embodiments, the same NN or a different NN can also be trained to output the control parameter (or adjustment thereto) per segment. For example, the used NN is pre-trained using labeled segments in training SEM images, known thickness variances, and user-labeled dosage to apply in each labeled segments given the applicable thickness variance(s). In some embodiments, the output of block 906 can be input to the NN that the NN may generate a recommended adjustment of the control parameter. In yet further embodiments, blocks 906 and 908 can be combined, whereby the SEM image is input and the NN outputs the recommended adjustment with or without the predicted thickness variance.

In the preceding description, various embodiments have been described. For purposes of explanation, specific configurations and details have been set forth in order to provide a thorough understanding of the embodiments. However, it will also be apparent to one skilled in the art that the embodiments may be practiced without the specific details. Furthermore, well-known features may have been omitted or simplified in order not to obscure the embodiment being described. While example embodiments described herein center on dual beam (e.g., electron and ion beams) microscopy systems, these are meant as non-limiting, illustrative embodiments. Embodiments of the present disclosure are not limited to such materials, but rather are intended to address charged particle beam systems for which a wide array of particles can be applied to imaging, microanalysis, and/or processing of materials on an atomic scale. Such particles may include, but are not limited to, electrons, ions, or photons in TEM systems, SEM systems, STEM systems, ion beam systems, and/or particle accelerator systems.

Some embodiments of the present disclosure include a system including one or more data processors and/or logic circuits. In some embodiments, the system includes a non-transitory computer readable storage medium containing instructions (e.g., executable instructions, one or more computer programs, or one or more applications) which, when executed on the one or more data processors, cause the one or more data processors to perform part or all of one or more methods and/or part or all of one or more processes and workflows disclosed herein. Some embodiments of the present disclosure include a computer-program product tangibly embodied in a non-transitory machine-readable storage medium, for example, in the form of a computer program including a plurality of instructions executable by one or more processors. The instructions can be configured to cause one or more data processors to perform part or all of one or more methods and/or part or all of one or more processes disclosed herein, including, for example, process 600, process 800, and process 900 of FIGS. 6, 8, and 9, respectively.

FIG. 10 depicts a block diagram of an example computer system usable with systems and methods according to embodiments of the present disclosure. Any of the computer systems mentioned herein may utilize any suitable number of subsystems. Examples of such subsystems are shown in FIG. 10 in computer system 1000. In some embodiments, a computer system includes a single computer apparatus, where the subsystems can be the components of the computer apparatus. In other embodiments, a computer system can include multiple computer apparatuses, each being a subsystem, with internal components. A computer system can include desktop and laptop computers, tablets, mobile phones and other mobile devices.

The subsystems shown in FIG. 10 are interconnected via a system bus 1027. Additional subsystems such as a printer 1024, keyboard 1028, storage device(s) 1029, monitor 1026 (e.g., a display screen, such as an LED), which is coupled to display adapter 1082, and others are shown. Peripherals and input/output (I/O) devices, which couple to I/O controller 1021, can be connected to the computer system by any number of means known in the art such as input/output (I/O) port 1025 (e.g., USB, FireWire®). For example, I/O port 1025 or external interface 1081 (e.g., Ethernet, Wi-Fi, etc.) can be used to connect computer system 1000 to a wide area network such as the Internet, a mouse input device, or a scanner. The interconnection via system bus 1027 allows the central processor 1023 to communicate with each subsystem and to control the execution of a plurality of instructions from system memory 1022 or the storage device(s) 1029 (e.g., a fixed disk, such as a hard drive, or optical disk), as well as the exchange of information between subsystems. The system memory 1022 and/or the storage device(s) 1029 may embody a computer readable medium. Another subsystem is a data collection device 1085, such as a camera, microphone, accelerometer, and the like. Any of the data mentioned herein can be output from one component to another component and can be output to the user.

A computer system can include a plurality of the same components or subsystems, e.g., connected together by external interface 1081, by an internal interface, or via removable storage devices that can be connected and removed from one component to another component. In some embodiments, computer systems, subsystem, or apparatuses can communicate over a network. In such instances, one computer can be considered a client and another computer a server, where each can be part of a same computer system. A client and a server can each include multiple systems, subsystems, or components.

Aspects of embodiments can be implemented in the form of control logic using hardware circuitry (e.g., an application specific integrated circuit or field programmable gate array) and/or using computer software stored in a memory with a generally programmable processor in a modular or integrated manner, and thus a processor can include memory storing software instructions that configure hardware circuitry, as well as an FPGA with configuration instructions or an ASIC. As used herein, a processor can include a single-core processor, multi-core processor on a same integrated chip, or multiple processing units on a single circuit board or networked, as well as dedicated hardware. Based on the disclosure and teachings provided herein, a person of ordinary skill in the art will know and appreciate other ways and/or methods to implement embodiments of the present disclosure using hardware and a combination of hardware and software.

Any of the software components or functions described in this application may be implemented as software code to be executed by a processor using any suitable computer language such as, for example, Java, C, C++, C #, Objective-C, Swift, or scripting language such as Perl or Python using, for example, conventional or object-oriented techniques. The software code may be stored as a series of instructions or commands on a computer readable medium for storage and/or transmission. A suitable non-transitory computer readable medium can include random access memory (RAM), a read only memory (ROM), a magnetic medium such as a hard-drive or a floppy disk, or an optical medium such as a compact disk (CD) or DVD (digital versatile disk) or Blu-ray disk, flash memory, and the like. The computer readable medium may be any combination of such devices. In addition, the order of operations may be re-arranged. A process can be terminated when its operations are completed but could have additional blocks not included in a figure. A process may correspond to a method, a function, a procedure, a subroutine, a subprogram, etc. When a process corresponds to a function, its termination may correspond to a return of the function to the calling function or the main function.

Such programs may also be encoded and transmitted using carrier signals adapted for transmission via wired, optical, and/or wireless networks conforming to a variety of protocols, including the Internet. As such, a computer readable medium may be created using a data signal encoded with such programs. Computer readable media encoded with the program code may be packaged with a compatible device or provided separately from other devices (e.g., via Internet download). Any such computer readable medium may reside on or within a single computer product (e.g., a hard drive, a CD, or an entire computer system), and may be present on or within different computer products within a system or network. A computer system may include a monitor, printer, or other suitable display for providing any of the results mentioned herein to a user.

According to various embodiments described herein, a gradient-based approach that includes using a single mill pattern to enable gradients in an applied dose between the endpoint segment regions, thereby reducing or eliminating any discontinuities between segments and/or within segments. Adjusting the relative dose of the individual pixels within each patterning line produces a more uniform final finish on the lamella surface and avoids sudden jumps or discontinuities in lamella thickness which are undesirable. Embodiments of automated lamella preparation as described herein provide an even and uniform thickness across the entire lateral dimension of the lamella.

Any of the methods described herein may be totally or partially performed with a computer system including one or more processors, which can be configured to perform the blocks. Any operations performed with a processor (e.g., aligning, determining, comparing, computing, calculating) may be performed in real-time. The term “real-time” may refer to computing operations or processes that are completed within a certain time constraint. The time constraint may be 1 minute, 1 hour, 1 day, or 7 days. Thus, embodiments can be directed to computer systems configured to perform the blocks of any of the methods described herein, potentially with different components performing a respective block or a respective group of blocks. Although presented as numbered blocks, blocks of methods herein can be performed at a same time or at different times or in a different order. Additionally, portions of these blocks may be used with portions of other blocks from other methods. Also, all or portions of a block may be optional. Additionally, any of the blocks of any of the methods can be performed with modules, units, circuits, or other means of a system for performing these blocks.

In the foregoing specification, embodiments of the disclosure have been described with reference to numerous specific details that can vary from implementation to implementation. The specification and drawings are, accordingly, to be regarded in an illustrative rather than a restrictive sense. The sole and exclusive indicator of the scope of the disclosure, and what is intended by the applicants to be the scope of the disclosure, is the literal and equivalent scope of the set of claims that issue from this application, in the specific form in which such claims issue, including any subsequent correction. The specific details of particular embodiments can be combined in any suitable manner without departing from the spirit and scope of embodiments of the disclosure.

Additionally, spatially relative terms, such as “bottom” or “top” and the like can be used to describe an element and/or feature's relationship to other element(s) and/or feature(s) as, for example, illustrated in the figures. It will be understood that the spatially relative terms are intended to encompass different orientations of the device in use and/or operation in addition to the orientation depicted in the figures. For example, if the device in the figures is turned over, elements described as a “bottom” surface can then be oriented “above” other elements or features. The device can be otherwise oriented (e.g., rotated 90 degrees or at other orientations) and the spatially relative descriptors used herein interpreted accordingly.

Terms “and,” “or,” and “an/or,” as used herein, may include a variety of meanings that also is expected to depend at least in part upon the context in which such terms are used. Typically, “or” if used to associate a list, such as A, B, or C, is intended to mean A, B, and C, here used in the inclusive sense, as well as A, B, or C, here used in the exclusive sense. In addition, the term “one or more” as used herein may be used to describe any feature, structure, or characteristic in the singular or may be used to describe some combination of features, structures, or characteristics. However, it should be noted that this is merely an illustrative example and claimed subject matter is not limited to this example. Furthermore, the term “at least one of” if used to associate a list, such as A, B, or C, can be interpreted to mean any combination of A, B, and/or C, such as A, B, C, AB, AC, BC, AA, AAB, ABC, AABBCCC, etc.

Reference throughout this specification to “one example,” “an example,” “certain examples,” or “exemplary implementation” means that a particular feature, structure, or characteristic described in connection with the feature and/or example may be included in at least one feature and/or example of claimed subject matter. Thus, the appearances of the phrase “in one example,” “an example,” “in certain examples,” “in certain implementations,” or other like phrases in various places throughout this specification are not necessarily all referring to the same feature, example, and/or limitation. Furthermore, the particular features, structures, or characteristics may be combined in one or more examples and/or features.

In some implementations, operations or processing may involve physical manipulation of physical quantities. Typically, although not necessarily, such quantities may take the form of electrical or magnetic signals capable of being stored, transferred, combined, compared, or otherwise manipulated. It has proven convenient at times, principally for reasons of common usage, to refer to such signals as bits, data, values, elements, symbols, characters, terms, numbers, numerals, or the like. It should be understood, however, that all of these or similar terms are to be associated with appropriate physical quantities and are merely convenient labels. Unless specifically stated otherwise, as apparent from the discussion herein, it is appreciated that throughout this specification discussions utilizing terms such as “processing,” “computing,” “calculating,” “determining,” or the like refer to actions or processes of a specific apparatus, such as a special purpose computer, special purpose computing apparatus or a similar special purpose electronic computing device. In the context of this specification, therefore, a special purpose computer or a similar special purpose electronic computing device is capable of manipulating or transforming signals, typically represented as physical electronic or magnetic quantities within memories, registers, or other information storage devices, transmission devices, or display devices of the special purpose computer or similar special purpose electronic computing device.

In the preceding detailed description, numerous specific details have been set forth to provide a thorough understanding of claimed subject matter. However, it will be understood by those skilled in the art that claimed subject matter may be practiced without these specific details. In other instances, methods and apparatuses that would be known by one of ordinary skill have not been described in detail so as not to obscure claimed subject matter. Therefore, it is intended that claimed subject matter is not limited to the particular examples disclosed, but that such claimed subject matter may also include all aspects falling within the scope of appended claims, and equivalents thereof.

What is claimed is:

1. A method comprising:
removing a first layer of material from a sample by at least directing a charged particle beam toward a surface of the sample in a pattern, the pattern corresponding to a segment of the sample;
generating, after the first layer is removed, a first image that shows at least the segment;
determining, based on the image, a variation in material removal between at least two sections of the segment;
determining, based on the variation in material removal, a control parameter that varies one or more properties of the charged particle beam across the at least two sections; and
removing a second layer of material from the sample by at least directing the charged particle beam in the pattern according to the control parameter.

2. The method of claim 1, wherein the control parameter includes at least one of: a dosage of the charged particle beam per section of the segment, an energy level of the charged particle beam per section of the segment, a dwell time of the charged particle beam per section of the segment, or a sweep time of the charged particle beam per section of the segment.

3. The method of claim 2, wherein the control parameter varies linearly across sections of the segment.

4. The method of claim 2, wherein the control parameter varies non-linearly across sections of the segment.

5. The method of claim 1, wherein each of the at least two sections is mapped to a set of pixels of the pattern, and wherein the control parameter varies across at least two pixel sets of the pattern.

6. The method of claim 1, wherein determining the variation in material removal between the at least two sections of the segment comprises determining a variation in thickness between the at least two sections of the segment.

7. The method of claim 1, further comprising:
outputting, by a neural network, an indication of a material removal variance across sections of the segment, wherein the control parameter is adjusted based on the indication.

8. The method of claim 7, further comprising:
outputting, by the neural network, a recommended adjustment for the control parameter.

9. The method of claim 1, wherein the at least two sections are adjacent.

10. The method of claim 1, wherein the at least two sections have a same width.

11. The method of claim 1, wherein the removal of the second layer of material is performed sequentially across sections of the segment.

12. The method of claim 1, wherein a total number of the sections is N, wherein N is predefined.

13. A system comprising:
a vacuum chamber;
a sample stage disposed in the vacuum chamber and configured to receive a sample in the vacuum chamber;
an ion beam column configured to provide an ion beam into the vacuum chamber; and
a controller comprising one or more processors and one or more memories storing computer-executable instructions that, when executed by the one or more processors, configure the controller to:
cause the ion beam column to remove a first layer of material from a sample by at least directing a charged particle beam toward a surface of the sample in a pattern, the pattern corresponding to a segment of the sample;
process, after the first layer is removed, a first image that shows at least the segment;
determine, based on the image, a variation in material removal between at least two sections of the segment;
determine, based on the variation in material removal, a control parameter that varies one or more properties of the charged particle beam across the at least two sections; and
cause removal of a second layer of material from the sample by at least directing the charged particle beam in the pattern according to the control parameter.

14. The system of claim 13, wherein the control parameter includes at least one of: a dosage of the charged particle beam per section of the segment, an energy level of the charged particle beam per section of the segment, a dwell time of the charged particle beam per section of the segment, or a sweep time of the charged particle beam per section of the segment.

15. The system of claim 14, wherein the control parameter varies linearly across sections of the segment.

16. The system of claim 14, wherein the control parameter varies non-linearly across sections of the segment.

17. The system of claim 13, wherein each of the at least two sections is mapped to a set of pixels of the pattern, and wherein the control parameter varies across at least two pixel sets of the pattern.

18. The system of claim 13, wherein determining the variation in material removal between the at least two sections of the segment comprises determining a variation in thickness between the at least two sections of the segment.

19. The system of claim 13, further comprising:
outputting, by a neural network, an indication of a material removal variance across sections of the segment, wherein determining the control parameter comprises adjusting the control parameter based on the indication.

20. A controller comprising:
one or more processors; and
one or more memories storing computer-executable instructions that, when executed by the one or more processors, configure the controller to:
cause an ion beam column to remove a first layer of material from a sample by at least directing a charged particle beam toward a surface of the sample in a pattern, the pattern corresponding to a segment of the sample;
cause, after the first layer is removed, a first image to be generated, the image showing at least one segment;
determine, based on the image, a variation in material removal between at least two sections of the segment;
determine, based on the variation in the material removal, a control parameter that varies one or more properties of the charged particle beam across the at least two sections; and
cause removal of a second layer of material from the sample by at least directing the charged particle beam in the pattern according to the control parameter.
